(19) United States
(12) Patent Application Publication
(10) Pub. No.: US 2026/0234792 A1
(43) Pub. Date: Aug. 13, 2026

(54) IN SITU CLEANING OF DEPOSITION CHAMBER WITH MICROWAVE PLASMA

(71) Applicant: Applied Materials, Inc., Santa Clara, CA (US)

(72) Inventors: Hanhong Chen, Milpitas, CA (US); Hao Zhang, San Jose, CA (US); Zhejun Zhang, Santa Clara, CA (US); Jianheng Li, Sunnyvale, CA (US); Victoria L. Chen, Sunnyvale, CA (US); Li Jia Peng, San Francisco, CA (US); Sanjeev Baluja, Campbell, CA (US); Joseph AuBuchon, San Jose, CA (US); Chi-Chou Lin, San Jose, CA (US)

(73) Assignee: Applied Materials, Inc., Santa Clara, CA (US)

(21) Appl. No.: 19/052,041

(22) Filed: Feb. 12, 2025

(51) Int. Cl. C23C 16/44; C23C 16/458; H01J 37/32

(52) U.S. Cl. CPC C23C 16/4405; C23C 16/4586; H01J 37/32256; H01J 37/32449; H01J 37/32853; H01J 2237/335

(57) ABSTRACT

Methods of cleaning a vapor deposition substrate processing chamber comprise injecting through a first gas injector having a front face and gas openings of the vapor deposition processing chamber a first cleaning gas mixture comprising first a fluorine-containing gas and a first inert gas at a first temperature and generating a first microwave plasma from the first cleaning gas mixture. The method includes exposing a pedestal including a substrate support surface of the vapor deposition chamber to a second cleaning gas mixture comprising a second fluorine-containing gas and a second inert gas and generating a second microwave plasma from the second cleaning gas mixture at a second temperature. The method includes heating the pedestal and the substrate support surface to a third temperature that is greater than the second temperature. The method removes AlFₓ cleaning residue.

### TECHNICAL FIELD

The present disclosure relates generally to methods of cleaning a substrate processing chamber with a microwave plasma. In particular, the disclosure relates to methods of cleaning components of a vapor deposition processing chamber.

### BACKGROUND

The semiconductor device industry continues to strive for larger production yields while increasing the uniformity of layers deposited on substrates such as semiconductor wafers. As circuit integration increases, the need for greater uniformity and process control of layer thickness rises. In some semiconductor device manufacturing processes, high quality films are deposited at low temperatures (e.g., below 450° C.) on a substrate such as a wafer supported on a pedestal in substrate processing chamber. Plasma-enhanced deposition processes are used to provide energy in the form of ions and radicals to the ALD film in addition to thermal energy.

Both direct and remote plasmas are used to generate plasma in plasma-enhanced vapor deposition processes. In microwave plasma processing chambers such as plasma enhanced chemical vapor deposition chambers and plasma enhanced atomic layer deposition chambers, microwave energy is applied through waveguides, causing the ignition of the gas into a plasma.

Film deposition on components of the substrate processing chamber, for example, on the edge of substrate support surface of a pedestal that supports a substrate during deposition of a film on the substrate, requires periodic cleaning of the components to reduce defects generated in the processing chamber due to film peeling and scratches caused by thermal expansion and rubbing of components by substrates. Conventionally, chamber cleaning is performed using a remote plasma source to generate radicals to clean chamber components including the substrate support surface of a pedestal.

There is a need for improved cleaning process of components, such as substrate support surfaces of pedestals of plasma enhanced vapor deposition processing chambers with high efficiency and low cost.

### SUMMARY

One or more embodiments of the disclosure are directed to a method of cleaning a vapor deposition substrate processing chamber, the method comprising injecting through a gas injector having a front face and gas openings of the vapor deposition substrate processing chamber a first cleaning gas mixture comprising a first fluorine-containing gas and a first inert gas at a first temperature; generating a first microwave plasma from the first cleaning gas mixture to clean the gas injector and a substrate support surface of a pedestal of the vapor deposition substrate processing chamber; injecting a second cleaning gas mixture comprising a second fluorine-containing gas and a second inert gas at a second temperature through the gas injector at a second temperature; generating a second microwave plasma from the second cleaning gas mixture to clean the gas injector and the substrate support surface of the vapor deposition substrate processing chamber; and heating the pedestal and a substrate support surface of the vapor deposition substrate processing chamber to a third temperature that is greater than the first temperature and the second temperature and generating third microwave plasma from a third cleaning gas including NH₃ and an inert gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow process diagram of one embodiment of a method of cleaning a plasma enhanced vapor deposition chamber;

FIG. 2 shows a cross-sectional isometric view of a plasma enhanced vapor deposition chamber in accordance with one or more embodiment of the disclosure;

FIG. 3 shows a cross-sectional view of a plasma enhanced vapor deposition chamber in accordance with one or more embodiment of the disclosure;

FIG. 4 shows a showerhead type gas diffuser including microwave resonators; and

FIG. 5 shows a partial view of a heater and support plate illustrating

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, “substrate” as used herein, refers to any substrate or material surface formed on a substrate upon which film processing is performed during a fabrication process. For example, a substrate surface on which processing can be performed includes materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers.

Embodiments of the disclosure pertain to an in-situ cleaning method for a plasma enhanced vapor deposition chamber such as a plasma enhanced vapor deposition (PECVD) or a plasma enhanced atomic layer deposition (PEALD) chamber.

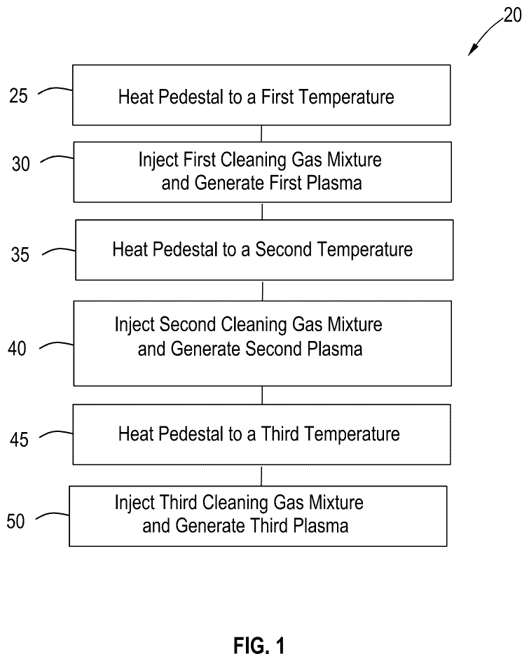

FIG. 1 depicts a flow diagram of a method 20 of cleaning a vapor deposition substrate processing chamber in accordance with one or more embodiments of the present disclosure. With reference to FIG. 1, the method 20 begins at operation 25, where a pedestal of the vapor deposition substrate processing chamber is heated to a first temperatures At operation 30, where a first cleaning gas mixture is injected into the vapor deposition substrate processing chamber and a first microwave plasma is generated directly in the chamber. The pressure in the chamber is at first pressure, and the gas injector openings are cleaned and the pedestal is cleaned. At operation 35, the pedestal is heated to a second temperature. At operation 40, a second cleaning gas mixture is injected into the through gas injector, and pedestal is exposed is exposed to second cleaning gas mixture and a second microwave plasma is generated directly in the chamber. At operation 45, the pedestal is heated to a third temperature, which in some embodiments is higher than the first temperature and the second temperature. At operation 50, a third cleaning gas mixture is injected through the gas injector and a third microwave plasma is generated directly in the vapor deposition substrate processing chamber.

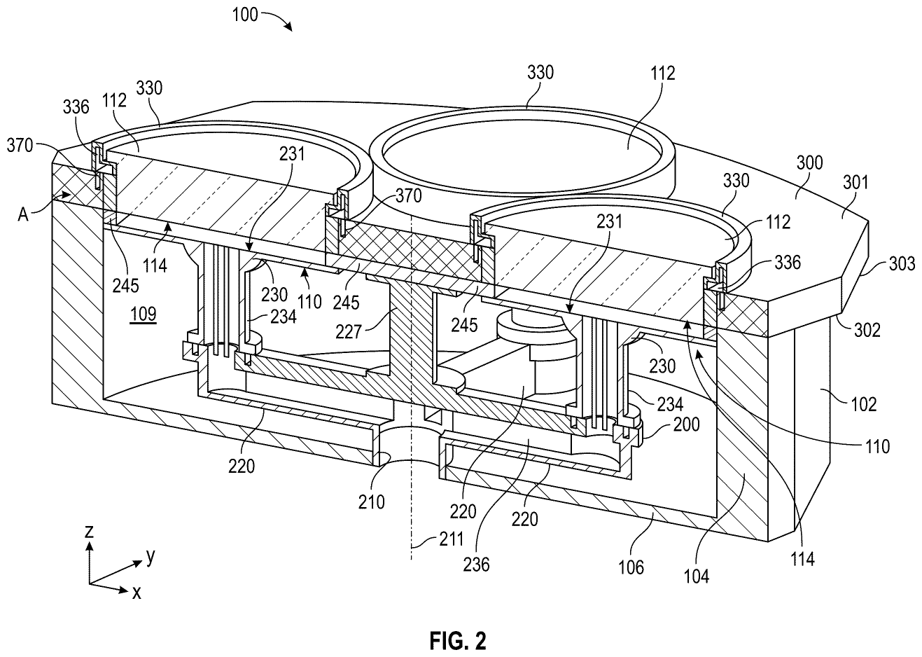

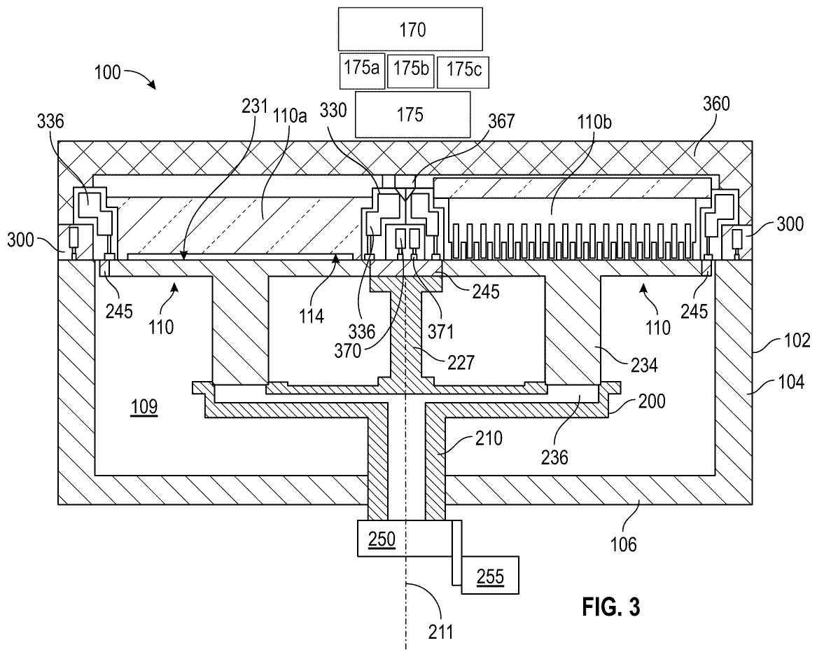

FIGS. 2 and 3 illustrate a processing chamber 100 having a plurality of substrate processing stations 110 that are cleaned in accordance with one or more embodiments of the disclosure. FIG. 2 shows the processing chamber 100 illustrated as a cross-sectional isometric view in accordance with one or more embodiments of the disclosure. FIG. 3 shows a processing chamber 100 in cross-section according to one or more embodiment of the disclosure. Some embodiments of the disclosure are directed to processing chambers 100 that incorporate a support assembly 200 and top plate 300. The processing chamber 100 has a housing 102 with walls 104 and a bottom 106. The housing 102 and the top plate 300 define an interior volume 109, also referred to as a processing volume.

The processing chamber 100 includes the plurality of substrate processing stations 110. The substrate processing stations 110 are located in the interior volume 109 of the housing 102 and are positioned in a circular arrangement around the rotational axis 211 of the support assembly 200. Each substrate processing station 110 comprises a gas injector 112 having a front face 114. In some embodiments, the front faces 114 of each of the gas injectors 112 are substantially coplanar.

The processing stations substrate are defined as a region in which processing of substrates can occur. In one or more embodiments, a substrate processing station 110 can be defined by the substrate support surface 231 of a pedestal 230 which is heated, as described below, and the front face 114 of the gas injectors 112.

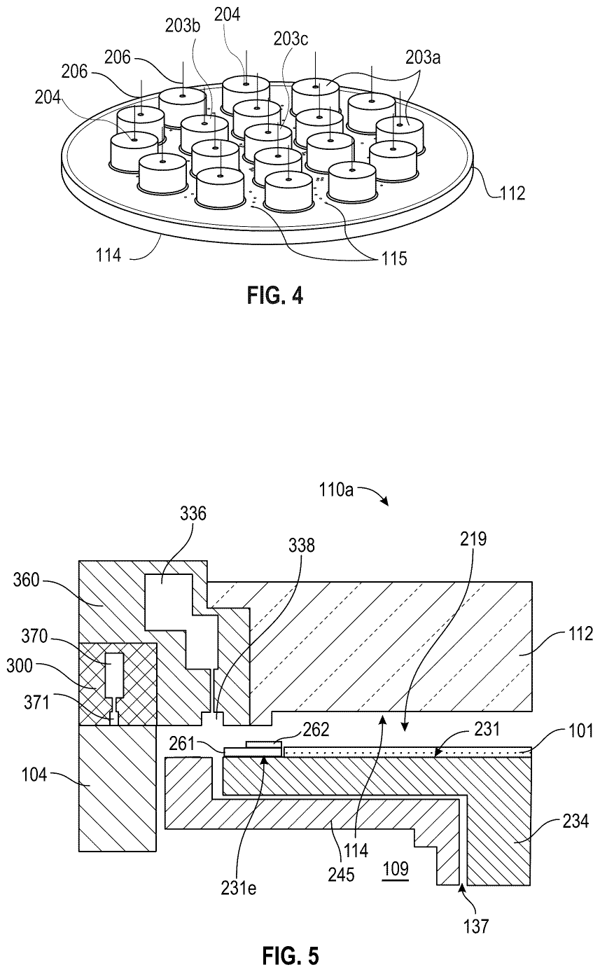

In some embodiments, the substrate processing stations 110 have a gas flow pattern from one or more of a gas diffuser, a cooling channel, or a pedestal. In some embodiments, the gas injector (or gas diffuser) 112 is a showerhead type gas diffuser and has a symmetrical hole pattern. Referring to FIG. 4, in other embodiments, the processing station 110 is configured to operate as a plasma station and the gas injector 112 is a plasma station having a pixelated geometry to produce a pixelated plasma pattern.

The substrate processing stations 110 can be configured to perform any suitable process and provide any suitable process conditions. In specific embodiments, one or more of the substrate processing stations 110 are configured to generate a plasma used in a plasma enhanced process such as PECVD or PEALD. The type of gas injector 112 used will depend on, for example, the type of process being performed and the type of showerhead or gas injector. For example, a substrate processing station 110 configured to operate as an atomic layer deposition apparatus may have a showerhead or vortex type gas injector. A substrate processing station 110 configured to operate as a plasma station may have one or more electrode and/or grounded plate configuration to generate a plasma while allowing a plasma gas to flow toward the wafer. The embodiment illustrated in FIG. 3 has a different type of substrate processing station 110 on the left side (substrate processing station 110a) of the drawing than on the right side (substrate processing station 110b) of the drawing. Suitable substrate processing stations 110 include, but are not limited to, thermal processing stations, microwave plasma, three-electrode capacitively couple plasma (CCP), inductively coupled plasma (ICP), parallel plate CCP, UV exposure, laser processing, pumping chambers, annealing stations and metrology stations.

Each support assembly 200 includes a center base 210. The center base 210 can have a symmetrical or asymmetrical shape and defines a rotational axis 211. The rotational axis 211 extends in a first direction. The first direction may be referred to as the vertical direction or along the z-axis; however, it will be understood that the use of the term “vertical” in this manner is not limited to a direction normal to the pull of gravity.

The support assembly 200 includes at least two support arms 220 connected to and extending from the center base 210. The support arms 220 have an inner end 221 and an outer end 222. The inner end 221 is in contact with the center base 210 so that when the center base 210 rotates around the rotational axis 211, the support arms 220 rotate as well. The support arms 220 can be connected to the center base 210 at the inner end 221 by fasteners (e.g., bolts) or by being integrally formed with the center base 210.

In some embodiments, the support arms 220 extend orthogonal to the rotational axis 211 so that one of the inner ends 221 or outer ends 222 are further from the rotational axis 211 than the other of the inner ends 221 and outer ends 222 on the same support arm 220. In some embodiments, the inner end 221 of the support arm 220 is closer to the rotational axis 211 than the outer end 222 of the same support arm 220.

The number of support arms 220 in the support assembly 200 can vary. In some embodiments, there are at least two support arms 220, at least three support arms 220, at least four support arms 220, or at least five support arms 220. In some embodiments, there are three support arms 220. In some embodiments, there are four support arms 220. In some embodiments, there are five support arms 220. In some embodiments, there are six support arms 220.

The support arms 220 can be arranged symmetrically around the center base 210. For example, in a support assembly 200 with four support arms 220, each of the support arms 220 are positioned at 90° intervals around the center base 210. In a support assembly 200 with three support arms 220, the support arms 220 are positioned at 120° intervals around the center base 210. Stated differently, in embodiments with four support arms 220, the support arms are arranged to provide four-fold symmetry around the rotation axis 211. In some embodiments, the support assembly 200 has n-number of support arms 220 and the n-number of support arms 220 are arranged to provide n-fold symmetry around the rotation axis 211.

A pedestal 230 is positioned at the outer end 222 of the support arms 220. In some embodiments, each support arm 220 has a pedestal 230, which in some embodiments is heated. The center of the pedestals 230 are located at a distance from the rotational axis 211 so that upon rotation of the center base 210 the pedestals 230 move in a circular path. The pedestals 230 have a substrate support surface 231 which can support a wafer. In some embodiments, the pedestal 230 and the substrate support surfaces 231 are substantially coplanar.

In some embodiments, the pedestals 230 are positioned directly on the outer end 222 of the support arms 220. In some embodiments, as illustrated in the drawings, the pedestals 230 are elevated above the outer end 222 of the support arms 220 by a pedestal standoff 234. The pedestal standoffs 234 can be any size and length to increase the height of the pedestals 230.

In some embodiments, a channel 236 is formed in one or more of the center base 210, the support arms 220 and/or the pedestal standoffs 234. The channel 236 can be used to route electrical connections or to provide a gas flow.

The pedestals 230 can be any suitable type of pedestal suitable for use in a semiconductor substrate processing chamber. In some embodiments, the pedestal 230 is heated and includes a resistive heater with one or more heating elements within a pedestal body. The pedestals 230 of some embodiments include additional components. For example, the pedestals may comprise an electrostatic chuck. The electrostatic chuck can include various wires and electrodes so that a wafer positioned on the substrate support surface 231 can be held in place while the pedestal is moved. This allows a wafer to be chucked onto a pedestal at the beginning of a process and remain in that same position on that same pedestal while moving to different process regions. In some embodiments, the wires and electrodes are routed through the channels 236 in the support arms 220. The channel 236 extends along the support arm 220 and the pedestal standoff 234.

In some embodiments, a support plate 245 is a single component that surrounds all of the pedestals 230 and has openings to allow access to the substrate support surface 231 of the pedestals 230. The openings can allow the pedestals 230 to pass through the support plate 245. In some embodiments, the support plate 245 is fixed so that the support plate 245 moves vertically and rotates with the pedestals 230. In some embodiments, the support plate 245 is supported by support post 227.

In one or more embodiments, one or more vacuum streams and/or purge gas streams can be used to help isolate one substrate processing station 110a from an adjacent substrate processing station 110b. A purge gas plenum 370 can be in fluid communication with a purge gas port 371 at the outer boundary of the substrate processing stations 110. In the embodiment illustrated, the purge gas plenum 370 and purge gas port 371 are located in the top plate 300. Plenum 336, shown as part of the pump/purge insert 330, is in fluid communication with an opening (a vacuum port) at the bottom of the plenum 336, which acts as a pump/purge gas port. The pump/purge insert 330 is shown in contact with the pedestal 230 and a support plate 245. The purge gas port 371 and purge gas plenum 370 and the opening (the vacuum port) can extend around the perimeter of the substrate processing station 110 to form a gas curtain. The gas curtain can help minimize or eliminate leakage of process gases into the interior volume 109 of the processing chamber.

In some embodiments, the top plate 300 includes a bar 360 that passes over a center portion of the top plate 300. The bar 360 can be connected to the top plate 300 near the center using connector 367. The connector 367 can be used to apply force orthogonal to the top or bottom of the top plate 300 to compensate for bowing in the top plate 300 as a result of pressure differentials or due to the weight of the top plate 300.

In some embodiments, as illustrated in FIG. 3, the support assembly 200 includes at least one motor 250. The at least one motor 250 is connected to the center base 210 and is configured to rotate the support assembly 200 around the rotational axis 211. In some embodiments, the at least one motor is configured to move the center base 210 in a direction along the rotational axis 211. For example, in FIG. 3, second motor 255 is connected to the first motor 250 and can move the support assembly 200 along the rotational axis 211. Stated differently, the second motor 255 illustrated can move the support assembly 200 along the z-axis, vertically or orthogonally to the movement caused by the first motor 250. In some embodiments, as illustrated, there is a first motor 250 to rotate the support assembly 200 around the rotational axis 211 and a second motor 255 to move the support assembly 200 along the rotational axis 211 (i.e., along the z-axis or vertically).

A direct microwave plasma refers to a microwave plasma that is generated in the vapor deposition substrate processing chamber adjacent to processing region in the area of the substrate support. A remote microwave plasma refers to a microwave plasma that is generated outside the substrate processing chamber and that is delivered to the interior of the substrate processing chamber. With a direct microwave plasma, only neutral reactive species (radicals) reach the substrate support. In some embodiments, the direct microwave plasma is generated through a dielectric resonator that is part of distance between the open end of the applicator housing 355 and the substrate surface is less than or equal to 100 mm, less than or equal to 80 mm, less than or equal to 60 mm, or less than or equal to 50

Showerhead assemblies used in the microwave plasma processes are comprised of a dielectric faceplate and a plurality of gas openings in the dielectric faceplate. The dielectric faceplate is made from a dielectric material such as alumina (AlOₓ), quartz (SiOₓ) and aluminum nitride (AlN).

FIG. 4 shows an embodiment of a gas injector 112 that can be used in the plasma enhanced vapor deposition chamber shown in FIG. 2 and FIG. 3. The gas injector 112 has the front face 114 and a plurality of resonators 203a, 203b, 203c in a symmetrical pixelated pattern. The pixelated pattern comprises outer peripheral edge resonators 203a, surrounding internal ring resonators 203b, which surrounds a central resonator 203c. In the embodiment shown, the peripheral edge resonators 203a are arranged in an outer ring adjacent to the peripheral edge of the gas injector 112 that is concentric with the internal ring resonators 203b arranged in an inner ring, which surround a single central resonator 203c that is at the center of the inner ring and the outer ring.

In one or more embodiments, there are at least 8, 9, 10, 11, or 12 peripheral edge resonators 203a arranged in a ring adjacent to the peripheral edge of the gas injector 112. In some embodiments, there is a range of from 8 to 15, 8 to 14, 8 to 13, 8 to 12, 8 to 11 or 8 to 10 peripheral edge resonators 203a arranged in a ring adjacent to the peripheral edge of the of the gas injector 112. The peripheral edge resonators 203a may also be referred to outer resonators. In some embodiments, there are at least 3, 4, 5, 6 or 7, for example 3 to 5, 3 to 6 or 3 to 7 internal ring resonators 203b arranged in a ring concentric with and bounded by the peripheral edge resonators 203a. In one or more embodiments, there is a single central resonator 203. The internal ring resonators 203b and the central resonator 203c in some embodiments are referred to as a group called internal resonators 203b, 203c. In a specific embodiment, there are 19 resonators comprising 12 peripheral edge resonators 203a arranged in a ring and surrounding 6 internal ring resonators 203b and a single central resonator 203c. The gas injector has a plurality of gas openings 115 spaced between the resonators 203a, 203b, and 203c.

Each of the plurality of dielectric resonators 203 have a geometric center and an opening 204 at the geometric center configured to receive a microwave antenna 206. In some embodiments, the microwave antenna 206 is a monopole antenna. In the embodiment shown, the opening 204 configured to receive the microwave antenna 206 is in the geometric center of each of the dielectric resonators 203.

Microwave power is supplied to the resonators 203a, 2023b, and 203c generated via the antenna in each of the microwave resonators 203a, 203b, 203c by a microwave power generator 175, which includes microwave amplification circuitry 175a comprising solid state microwave circuitry. A voltage control circuit 175b provides an input voltage to a voltage-controlled oscillator 175c configured to produce microwave radiation at a desired frequency that is transmitted to the microwave amplification circuitry 175a and transmitted to the resonators 203a, 203b, and 203c. The voltage can be delivered in a continuous wave mode or a pulsed mode.

A controller 170 is configured to control the microwave generator 175, including the microwave amplification circuitry 175a and the voltage control circuit 175b, and to clean the chamber components. The controller 170 is further configured to control operation of the vacuum pump 135, delivery of a cleaning gas comprising a cleaning gas mixture of a fluorine-containing gas and an inert gas and the reactive gas from an inert gas supply and a fluorine-containing gas supply.

Referring now to FIG. 5, which shows a partial view of the pedestal 230 and support plate 245 and a portion of the one substrate processing station 110a and a wafer 101 that is exposed to a microwave plasma in a processing region 219 during a plasma enhanced atomic layer deposition process. Wafers processed in substrate processing station 110a have a smaller diameter (e.g., 200 mm, 300 mm) than the substrate support surface 231, and there is an exposed edge region 231e of the substrate support surface 231 during a film formation process such as PEALD. Films deposited on exposed components of the substrate processing station 110a require that the substrate processing station must be periodically cleaned to reduce generation of defects due to peeling and/or scratching of the deposited films.

It was determined that films deposited on the components could not be cleaned from the components, for example, the exposed edge region 321 of the substrate support surface 231 during a film formation process such as PEALD. Some PEALD substrate processing chambers use a capacitive plasma sources in RF/VHF frequency band up to several tens of MHz, for example at 13.6 MHz or 60 MHz. Capacitive plasmas have moderate plasma densities and can have relatively high ion energies. On the other hand, microwave plasmas operate at frequencies greater than 300 MHz, for example, 2.45 GHZ, and have very high charge and plasma densities compared to capacitive plasma sources. The typical plasma densities can be one or two orders higher than RF plasma and ion energies can be as low as less than 10 eV.

The microwave plasma densities in some embodiments range from 10¹¹/cm³ to 10¹³/cm³, and ion energies in some embodiments are less than 10 eV. The direct microwave plasma generated immediately above the substrate support surface 231 surface generates ions and radicals during the cleaning process with a high plasma density.

In some embodiments, the microwave plasma has a power in the range of 0.5 kW to 12 KW. In some embodiments, the microwave plasma is a continuous wave plasma with a power in the range of 0.5 KW to 12 KW, in the range of 0.5 KW to 5 kW, in the range of 1 KW to 4 KW, in the range of 2 KW to 4 kW, in the range of 3 KW to 4 KW, in the range of 3 KW to 11 KW, in the range of 4 KW to 10 KW, or in the range of 5 kW to 9 kW.

Advantageously, a direct microwave plasma which is generated adjacent to processing region 219 between the front face 114 of the gas injector 112 and the substrate support surface 231 is more effective than a remote plasma and other types of plasmas such as CCP and ICP plasmas. In addition, direct microwave plasm does not cause plasma damage to chamber components such as the substrate support surface, the gas injector, and process kits. In one or more embodiments, advantageously, the pixelated pattern of resonators 203a, 203b, and 203c shown in FIG. 4 is controlled by the controller 170. The controller is configured to activate selected resonators 203a, 203b and 203c to clean only selected regions of the substrate processing chamber and the components. In one or more embodiments, the process includes activating only the peripheral edge resonators 203a clean one or more films on the edge region 231e of the substrate support surface 231 while the central resonator 203c and the internal resonators 203b are not activated during the cleaning process to clean the edge region 231e. In other embodiments, the peripheral edge resonators 203a are activated for a longer period of time than the internal resonators 203b, 203c during the cleaning process. The one or more films may comprise a first film 261 on the substrate surface and a second film 262 on the first film 261.

In a specific embodiment the process includes first setting the temperature of the pedestal 230 and the substrate support surface 231 to a first temperature of less than 500° C., less than 450° C., less than 350° C., less than 300° C., or less than 275° C. and greater than 100° C., for example, in a range of from 200 to 450° C., in a range of from 230 to 275° C., in a range of from 240 to 270° C., in a range of from 245 to 265° C., or in range of from 250 to 260° C.

After setting the temperature of the pedestal 230 to a first temperature, a first cleaning gas mixture is injected through the gas injector 112 including the gas openings 115, which are cleaned at a first pressure in a range of from 0.5 to 2.5 Torr, or 0.5 to 2 Torr, or 1 to 1.5 Torr, for example, 1.25 Torr using the first cleaning gas mixture comprising a first fluorine-containing gas and a first inert gas. The first fluorine-containing gas is selected from the group consisting of NF₃, ClF₃, F₂, CF₄, O₂F₆, and combinations thereof. The first inert gas is selected from the group consisting of helium, argon, and combinations thereof. The first fluorine-containing gas is present in the first cleaning gas mixture in a range of from 0.1 to 20%, 0.1% to 15%, 0.1 to 10% or 0.1 to 5% of the first cleaning gas mixture on a molar basis. In one or more embodiments, the first gas mixture is flowed at a flow rate in a range of from 1000 to 6000 standard cubic centimeters per minute (sccm). In a specific embodiment, the first fluorine-containing gas comprises NF₃ or F₂ mixed with argon, and in a more specific embodiment the first cleaning gas mixture comprises, consists essentially of, or consists of a NF₃/Ar mixture. As used herein, the phrase “consisting essentially of” means the cleaning gas mixture comprises the fluorine-containing gas and the inert gas in an amount that is greater than or equal to 95%, 98%, 99% or 99.5% of the cleaning gas mixture. The lower pressure cleans the gas injector 112 and the gas openings, while also cleaning the substrate support surface 231.

The gas injector 112 including the gas openings 115 and the substrate support surface 231 are cleaned by generating a first microwave plasma from the first cleaning gas mixture using microwave plasma described above as described above using the microwave power generator 175 and the resonators 203a, 203b and 203c to generate the first microwave plasma having a power in the range of 0.5 KW to 12 KW. In some embodiments, the first microwave plasma is a continuous wave plasma with a power in the range of 0.5 KW to 12 KW, in the range of 0.5 KW to 5 KW, in the range of 1 KW to 4 kW, in the range of 2 KW to 4 KW, in the range of 3 KW to 4 KW, in the range of 2 kW to 12 KW, in the range of 3 KW to 11 KW, in the range of 4 KW to 10 KW, or in the range of 5 KW to 9 KW. In some embodiments, the first microwave plasma is pulsed. In one or more embodiments, the material remove by the plasma is at a removal rate in a range 0.1 microns thickness/minute to 1 micron thickness/minute.

After exposing the gas injector to the first microwave plasma, the pedestal 230 is set to a second temperature, and the pedestal 230 and the substrate support surface 231 are exposed to a second cleaning gas mixture comprising a second fluorine-containing gas and an inert gas. The second cleaning as mixture is injected through the gas openings 115 of the gas injector 112, and the gas injector 112 and the gas openings 115 are also cleaning. Setting the temperature of the pedestal 230 and the substrate support surface 231 includes setting to a second temperature of less than 500° C., less than 350° C., less than 300° C., or less than 275° C. and greater than 100° C., for example in a range of from 230 to 275° C., in a range of from 240 to 270° C., in a range of from 245 to 265° C., or in range of from 250 to 260° C. The pedestal and the substrate support surface 231 are cleaned at a second pressure in a range of from 1 to 10 Torr, or 1 to 5 Torr, or 1 to 4 Torr, for example, 3 Torr using the second cleaning gas mixture, comprising a fluorine-containing gas. The second fluorine-containing gas is selected from the group consisting of NF₃, ClF₃, F₂, CF₄, O₂F₆, and combinations thereof. The second inert gas is selected from the group consisting of helium, argon, and combinations thereof. The second fluorine-containing gas is present in the second cleaning gas mixture in a range of from 1 to 20%, 1 to 15% or 1 to 10% of the second cleaning gas mixture on a molar basis. In one or more embodiments, the second cleaning gas mixture is flowed at a flow rate in a range of from 1000 to 6000 standard cubic centimeters per minute (sccm). In specific embodiment, the second fluorine-containing comprises NF₃ or F₂ mixed with argon, and in a more specific embodiment the second cleaning gas mixture comprises, consists essentially of, or consists of a NF₃/Ar mixture.

The gas injector 112, the gas openings 115, pedestal 230 and the substrate support surface 231 are cleaned by generating a second microwave plasma from the second cleaning gas mixture using a second microwave plasma as described above using the microwave power generator 175 and the resonators 203a, 203b and 203c to generate the second microwave plasma having a power in the range of 2 KW to 12 kW. In some embodiments, the second microwave plasma is a continuous wave plasma or a pulsed plasma with a power in the range of 0.5 kW to 12 KW, in the range of 0.5 KW to 5 kW, in the range of 1 KW to 4 KW, int the range of 2 KW to 4 KW, in the range of 3 KW to 4 KW, in the range of 2 KW to 12 KW, or in the range of 3 KW to 11 KW, or in the range of 4 KW to 10 KW, or in the range of 5 KW to 9 KW. In one or more embodiments, the material remove by the plasma is at a removal rate in a range 0.1 microns thickness/minute to 1 micron thickness/minute.

In one or more embodiments, after cleaning the gas injector 112 including the gas openings 115 and the substrate support surface 231, the pedestal 230 and the substrate support 231 surface are heated. The pedestal and the substrate support surface are heated to a third temperature greater than the first temperature and the second temperature, for example, in a range of from 300 to 600° C., 350 to 600° C., 400 to 600° C., 450 to 590° C., or 530 to 580° C., for example 550° C., 560° C., or 570° C. at a third pressure in a range of from 0.5 Torr to 20 Torr, 1 to 20 Torr, 1 to 15 Torr or 1 to 10 Torr. The third pressure is higher than the second pressure. A direct microwave plasma is generated from a third cleaning gas mixture comprising NH₃ and an inert gas selected from argon, helium and N₂ and combinations thereof injected through the gas openings 115 of the gas injector 112. In some embodiments the third cleaning gas mixture is NH₃ in N₂ and argon. The NHs is present in the third cleaning gas mixture in a range of from 1 to 20%, 1 to 15% or 1 to 10% of the second cleaning gas mixture on a molar basis.

Advantageously, embodiments of the cleaning process removes metal fluoride residue materials that may be present during the cleaning process, for example aluminum fluoride (AlFₓ, where x=1, 3, 6 or 9). In particular, removal of the residue material occurs during the third plasma exposure. The microwave plasma cleaning process removes AlFₓ, which avoids contamination of the interior of the chamber with AlFₓ when the chamber is used for a film deposition process.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of cleaning a vapor deposition substrate processing chamber, the method comprising:
injecting through a gas injector having a front face and gas openings of the vapor deposition substrate processing chamber a first cleaning gas mixture comprising a first fluorine-containing gas and a first inert gas at a first temperature;
generating a first microwave plasma from the first cleaning gas mixture to clean the gas injector and a substrate support surface of a pedestal of the vapor deposition substrate processing chamber;
injecting a second cleaning gas mixture comprising a second fluorine-containing gas and a second inert gas at a second temperature through the gas injector at a second temperature;
generating a second microwave plasma from the second cleaning gas mixture to clean the gas injector and the substrate support surface of the vapor deposition substrate processing chamber; and
heating the pedestal and a substrate support surface of the vapor deposition substrate processing chamber to a third temperature that is greater than the first temperature and the second temperature and generating third microwave plasma from a third cleaning gas mixture.

2. The method of claim 1, wherein the third cleaning gas mixture comprises NHs and an inert gas, and the method removes AlFₓ residue from the vapor deposition substrate processing chamber.

3. The method of claim 2, wherein the first microwave plasma, the second microwave plasma and the third microwave plasma are a direct microwave plasma generated at the gas injector at a frequency in a range of from 300 MHz to 10 GHZ and a power in the range of 0.5 kW to 12 kW.

4. The method of claim 3, wherein the gas injector comprises a plurality of resonators arranged in a pixelated pattern including internal resonators and external resonators adjacent to a peripheral edge of the gas injector.

5. The method of claim 1, further comprising setting a temperature of the pedestal and the substrate support surface to the first temperature in a range of from 200 to 450° C. and a vapor deposition substrate processing chamber pressure in the range of 0.5 Torr to 20 Torr.

6. The method of claim 5, wherein the first fluorine-containing gas and the second fluorine-containing gas are selected from the group consisting of NF₃, ClF₃, F₂, CF₄, O₂F₆, and combinations thereof.

7. The method of claim 5, wherein the first fluorine-containing gas and the second fluorine-containing gas are selected from the group consisting of NF₃, F₂, and combinations thereof.

8. The method of claim 5, wherein the first fluorine-containing gas and the second fluorine-containing gas are NF₃.

9. The method of claim 5, wherein the first inert gas and the second inert gas are selected from the group consisting of helium, argon, and combinations thereof.

10. The method of claim 5, wherein the first inert gas and the second inert gas are argon.

11. The method of claim 8, wherein the first inert gas and the second inert gas are argon.

12. The method of claim 5, wherein the first fluorine-containing gas is present in the first cleaning gas mixture in a range of from 0.1 to 20% of the first cleaning gas mixture on a molar basis.

13. The method of claim 5, wherein the second fluorine-containing gas is present in the second cleaning gas mixture in a range of from 1 to 20% of the second cleaning gas mixture on a molar basis.

14. The method of claim 5, wherein the third temperature is in a range of from 450 to 600° C.

15. The method of claim 14, where the third cleaning gas mixture comprises NH₃, argon and N₂.

16. The method of claim 4, wherein during generating the second microwave plasma, the external resonators adjacent to a peripheral edge of the gas injector are activated for a longer period of time than the internal resonators to clean an edge region of the substrate support.

17. A method of claim 16, wherein the internal resonators comprise an internal ring resonators concentric with and surrounded by the external resonators.

18. The method of claim 17, wherein the internal ring resonators surround a central resonator.

19. The method of claim 18, wherein there are 19 resonators.

20. The method of claim 16, further comprising controlling activation of the resonators with a controller.
